(19) United States
(12) Patent Application Publication
(10) Pub. No.: US 2025/0014949 A1
(43) Pub. Date: Jan. 9, 2025

(54) PROCESSING METHOD OF WAFER

(71) Applicant: DISCO CORPORATION, Tokyo (JP)

(72) Inventors: Akira MIZUTANI, Tokyo (JP); Yuki IKKU, Tokyo (JP); Takashi EYAMA, Tokyo (JP)

(21) Appl. No.: 18/761,685

(22) Filed: Jul. 2, 2024

(30) Foreign Application Priority Data
Jul. 6, 2023 (JP) 2023-111697

(51) Int. Cl. H01L 21/66; B23K 26/53; B23K 101/40; H01L 21/02; H01L 21/18

(52) U.S. Cl. CPC H01L 22/24; B23K 26/53; H01L 21/02013; H01L 21/187; B23K 2101/40

(57) ABSTRACT

A wafer processing method includes forming a bonded wafer by bonding a first wafer to a second wafer, irradiating a laser beam along a position separate inward from an outer circumferential edge by a predetermined distance in an annular manner and forming, inside the first wafer, an annular modified layer and cracks that extend from the modified layer toward a front surface side to cause warpage in the outer circumferential region. The method also includes detecting the amount of warpage of the outer circumferential region, determining whether or not bonding between the first wafer and the second wafer has been released on the basis of the amount of warpage of the outer circumferential region, deciding whether or not to execute a grinding step, and if so, grinding the first wafer from a back surface side.

### BACKGROUND OF THE INVENTION

### Field of the Invention

The present invention relates to a processing method of a wafer.

### Description of the Related Art

In association with reduction in a height and increase in a degree of integration regarding device chips in recent years, development of a semiconductor wafer three-dimensionally stacked has been advanced. For example, a through-silicon via (TSV) wafer enables connection between electrodes of two devices through bonding of both devices to each other by a through-electrode.

Such a wafer is ground and thinned in the state in which the wafer is bonded to a support wafer (silicon, glass, ceramic, or the like) that serves as a base. In general, the outer circumferential edge of the wafer is beveled. Thus, when the wafer is ground extremely thinly, the outer circumferential edge becomes a generally-called knife edge and chipping at the edge is likely to occur in the grinding. Due to this, there is a possibility that the chipping extends to a device and the breakage of the device is caused.

As a countermeasure against the knife edge, there has been devised an edge trimming method in which, after wafers are bonded to each other, irradiation with a laser beam is executed along the outer circumferential edge of a device region and an annular modified layer is formed to suppress extension of edge chipping of the wafer that occurs in grinding thereof to a device (refer to Japanese Patent Laid-open No. 2020-057709).

### SUMMARY OF THE INVENTION

However, in the method described in Japanese Patent Laid-open No. 2020-057709, in the case in which the modified layer is formed inside in the radial direction relative to a bonding region, there is a possibility that an end material of an outer circumferential region remains without being separated.

Thus, an object of the present invention is to provide a processing method of a wafer that can remove an outer circumferential region while suppressing the breakage of a device in a grinding step of a bonded wafer.

In accordance with an aspect of the present invention, there is provided a processing method of a wafer. The processing method of a wafer includes a bonded wafer forming step of forming a bonded wafer by bonding the front surface side of a first wafer to a second wafer. The first wafer has an outer circumferential chamfered edge. The processing method of a wafer includes also a modified layer forming step of, after execution of the bonded wafer forming step, executing irradiation with a laser beam with such a wavelength as to be transmitted through the first wafer from the back surface side of the first wafer along a position separate inward from the outer circumferential edge by a predetermined distance in an annular manner and forming, inside the first wafer, an annular modified layer and cracks that extend from the modified layer and extend toward the front surface side of the first wafer to cause warpage in an outer circumferential region on the side of the outer circumferential edge relative to the modified layer and the cracks. The processing method of a wafer includes also a detection step of detecting the amount of warpage of the outer circumferential region of the first wafer after execution of the modified layer forming step, a determination step of determining whether or not bonding between the first wafer and the second wafer in the outer circumferential region has been released on the basis of the amount of warpage of the outer circumferential region detected in the detection step, and a grinding step of grinding the first wafer of the bonded wafer from the back surface side to thin the first wafer to a finished thickness when it is determined that the amount of warpage of the outer circumferential region is equal to or larger than a predetermined value in the determination step.

Preferably, the modified layer forming step is executed again when it is determined that the amount of warpage of the outer circumferential region is smaller than the predetermined value in the determination step.

Preferably, the processing method of a wafer further includes an advance detection step of detecting the amount of warpage of the outer circumferential region in advance before the execution of the modified layer forming step and a comparison step of comparing the amount of warpage detected in the advance detection step with the amount of warpage detected in the detection step. In the determination step, whether or not the bonding between the first wafer and the second wafer in the outer circumferential region has been released is determined on the basis of a comparison result in the comparison step and whether or not to execute the grinding step is decided.

Preferably, in the detection step, the height of the outer circumferential region is measured and the amount of warpage of the outer circumferential region is detected on the basis of a measurement value of the height of the outer circumferential region.

Preferably, in the detection step, the outer circumferential region is irradiated with light and an interference fringe is acquired and the amount of warpage of the outer circumferential region is detected on the basis of the interference fringe generated in the outer circumferential region.

The present invention can remove the outer circumferential region while suppressing the breakage of a device in the grinding step of the bonded wafer.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating one example of a wafer that is a processing target of a processing method of a wafer according to an embodiment;

FIG. 2 is a sectional view along line II-II illustrated in FIG. 1;

FIG. 3 is a flowchart illustrating a flow of the processing method of a wafer according to the embodiment;

FIG. 4 is a perspective view illustrating one state of a bonded wafer forming step illustrated in FIG. 3;

FIG. 5 is a partially sectional side view illustrating one state of a modified layer forming step illustrated in FIG. 3;

FIG. 6 is a sectional view illustrating part of a bonded wafer after the modified layer forming step illustrated in FIG. 3 in an enlarged manner;

FIG. 7 is a sectional view illustrating part of the bonded wafer after the modified layer forming step illustrated in FIG. 3 in an enlarged manner;

FIG. 8 is a schematic diagram illustrating one example of a detection step illustrated in FIG. 3;

FIG. 9 is a diagram illustrating one example of a measurement result of the amount of warpage in the detection step illustrated in FIG. 3;

FIG. 10 is a partially sectional side view illustrating one state of a grinding step illustrated in FIG. 3; and

FIG. 11 is a flowchart illustrating the flow of a processing method of a wafer according to a modification example.

### DETAILED DESCRIPTION OF THE PREFERRED EMBODIMENT

An embodiment of the present invention will be described in detail below with reference to the drawings.

The present invention is not limited by contents described in the following embodiment. Furthermore, in constituent elements described below, what can be easily envisaged by those skilled in the art and what are substantially the same are included. Moreover, it is possible to combine configurations described below as appropriate. In addition, it is possible to execute various kinds of omission, replacement, or change of a configuration without departing from the gist of the present invention.

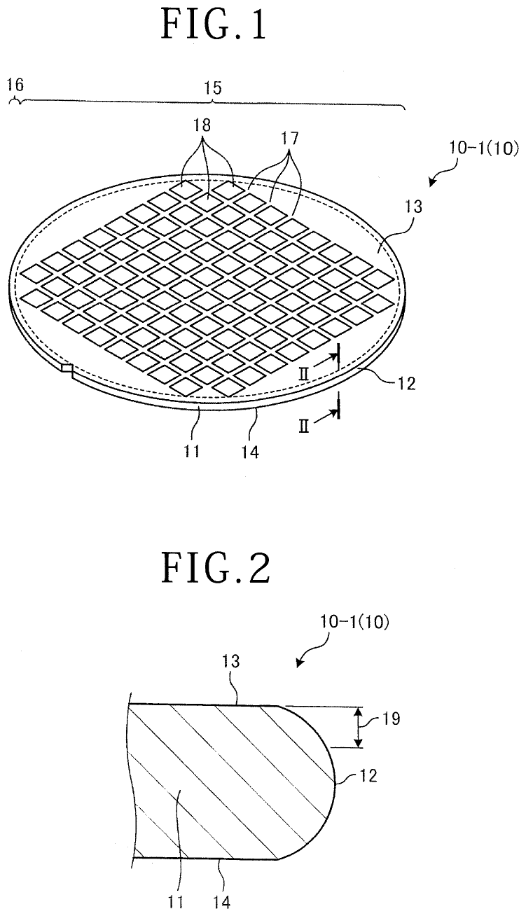

A processing method of a wafer 10 and a processing apparatus 30 according to the embodiment of the present invention will be described on the basis of drawings. First, the wafer 10 that is a processing target will be described. FIG. 1 is a perspective view illustrating one example of the wafer 10 that is the processing target of the processing method of the wafer 10 according to the embodiment. FIG. 2 is a sectional view along line II-II illustrated in FIG. 1.

The wafer 10 illustrated in FIGS. 1 and 2 is a wafer such as a semiconductor wafer or optical device wafer that has a circular plate shape and includes silicon (Si), sapphire (Al₂O₃), gallium arsenide (GaAs), silicon carbide (SiC), or the like as a substrate 11, and is a silicon wafer in the embodiment. Furthermore, the wafer 10 of the embodiment has a diameter of 300 mm and a thickness of 775 μm. An outer circumferential edge 12 of the wafer 10 is beveled in such a manner that, as illustrated in FIG. 2, the center in the thickness direction protrudes to the outer circumferential side to the largest extent and an arc shape is made in sectional view from a front surface 13 of the substrate 11 to a back surface 14.

As illustrated in FIG. 1, the wafer 10 has a device layer including a central region 15 and an outer circumferential region 16 that surrounds the central region 15 on the side of the front surface 13 of the substrate 11. The central region 15 has a plurality of planned dividing lines 17 set in a lattice manner in the front surface 13 of the substrate 11 and devices 18 formed in the respective regions marked out by the planned dividing lines 17. The outer circumferential region 16 is a region that surrounds the central region 15 across the whole circumference and in which the device 18 is not formed.

In the embodiment, the device 18 configures a 3D NAND flash memory and includes an electrode pad and a through-electrode that connects to the electrode pad. The through-electrode penetrates to the side of the back surface 14 of the substrate 11 when the substrate 11 is thinned and the devices 18 are individually divided from the wafer 10. That is, the wafer 10 of the embodiment is a generally-called TSV wafer in which the devices 18 individually divided have the through-electrode. Note that the wafer 10 of the present invention is not limited to the TSV wafer having the through-electrode as in the embodiment and may be a device wafer without the through-electrode.

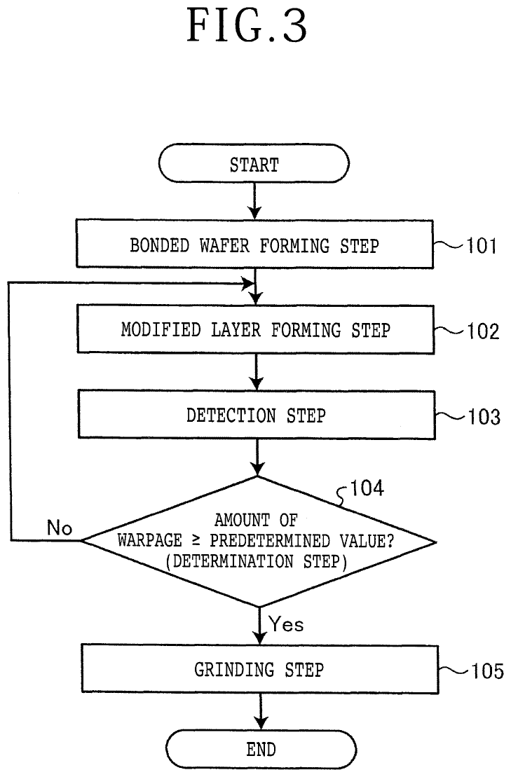

Next, the flow of the processing method of the wafer 10 will be described. FIG. 3 is a flowchart illustrating the flow of the processing method of the wafer 10 according to the embodiment. As illustrated in FIG. 3, the processing method of the wafer 10 in the embodiment includes a bonded wafer forming step 101, a modified layer forming step 102, a detection step 103, a determination step 104, and a grinding step 105. The processing method of the wafer 10 in the embodiment is a method in which the side of the front surface 13 of one wafer 10 (first wafer 10-1) is bonded to the other wafer 10 (second wafer 10-2) and a point of origin of dividing for removing the outer circumferential region 16 is formed and thereafter the one wafer 10 (first wafer 10-1) is thinned to a predetermined finished thickness 19.

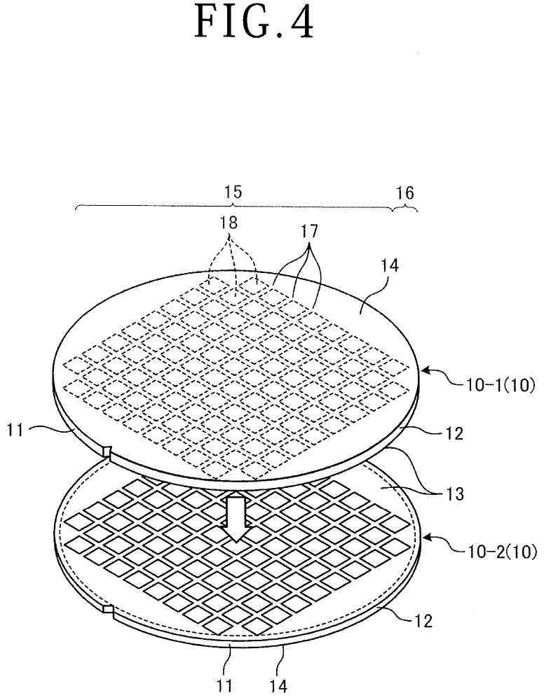

Incidentally, in description made hereinafter, when the wafers 10 in a pair of wafers 10 are discriminated from each other, the one wafer 10 will be referred to as the first wafer 10-1 and the other wafer 10 will be referred to as the second wafer 10-2 (see FIG. 4). When being not discriminated, they will be referred to as the wafer 10 simply. Description will be made on the basis of the assumption that the second wafer 10-2, which is not thinned, is a TSV wafer similar to the first wafer 10-1 in the embodiment. However, the second wafer 10-2 may be a mere substrate wafer without a pattern in the present invention.

### (Bonded Wafer Forming Step 101)

FIG. 4 is a perspective view illustrating one state of the bonded wafer forming step 101 illustrated in FIG. 3. The bonded wafer forming step 101 is a step of bonding the side of the front surface 13 of the first wafer 10-1 to the second wafer 10-2 to form a bonded wafer 20.

In the bonded wafer forming step 101, first, as illustrated in FIG. 4, the front surface 13 of the first wafer 10-1 and the front surface 13 of the second wafer 10-2 are made opposed to each other at an interval. Next, the front surface 13 of the first wafer 10-1 and the front surface 13 of the second wafer 10-2 are bonded to each other. This forms the bonded wafer 20.

At this time, in the case of disposing a bonding layer between the first wafer 10-1 and the second wafer 10-2, the front surface 13 of the first wafer 10-1 and the front surface 13 of the second wafer 10-2 are bonded to each other with the interposition of the bonding layer after the bonding layer is stacked on one of the front surface 13 of the first wafer 10-1 and the front surface 13 of the second wafer 10-2. Note that the bonding layer may be a double-sided tape in which adhesive layers are stacked on front and back surfaces of a base layer or be an oxide film or be what is formed by application of an adhesive containing a resin or the like.

Moreover, the first wafer 10-1 and the second wafer 10-2 may be directly bonded without using the bonding layer. In this case, for example, the following method may be employed. The first wafer 10-1 and the second wafer 10-2 are bonded to be provisionally bonded in the state in which at least either of the front surface 13 of the first wafer 10-1 and the front surface 13 of the second wafer 10-2 is activated by being subjected to plasma treatment. Thereafter, the strength of the bonding is enhanced by executing annealing treatment. In the plasma treatment, a plasma-like gas is supplied to the surface to be subjected to the plasma treatment by supplying high-frequency power in the state in which a process gas of argon (Ar), nitrogen (N₂), oxygen (O₂), or the like is supplied in a chamber under a vacuum.

Furthermore, the method of the annealing treatment may be, for example, single wafer rapid thermal anneal (RTA) in which the bonded wafer 20 is rapidly heated one by one inside a chamber or a batch system in which a plurality of bonded wafers 20 disposed in a furnace tube made of quartz are heated by a heater from the outside to be simultaneously subjected to thermal treatment. However, the method is not limited to heating by infrared rays and may be a method in which heating is executed by a hot plate. Note that the annealing treatment may be executed after the modified layer forming step 102 or the detection step 103 as long as it is executed before the grinding step 105 to be described later is executed.

Note that, although the side of the front surface 13 of the first wafer 10-1 and the side of the front surface 13 of the second wafer 10-2 are bonded to each other in the embodiment, the first wafer 10-1 may be bonded to either surface of the second wafer 10-2 when the second wafer 10-2 is a substrate wafer.

### (Modified Layer Forming Step 102)

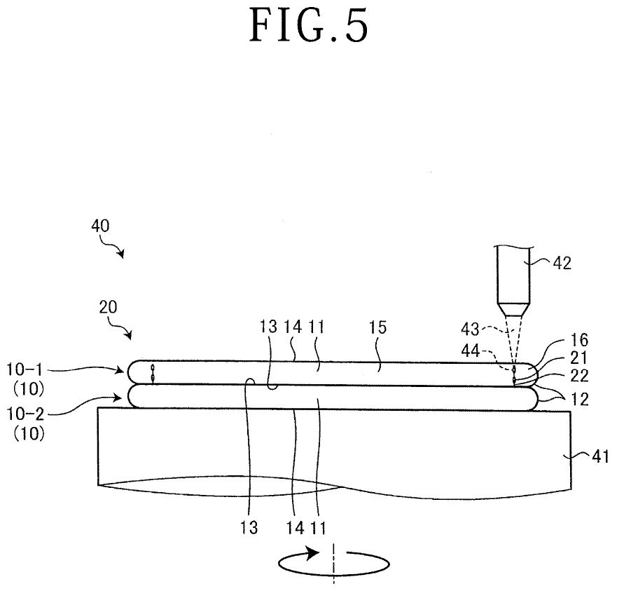

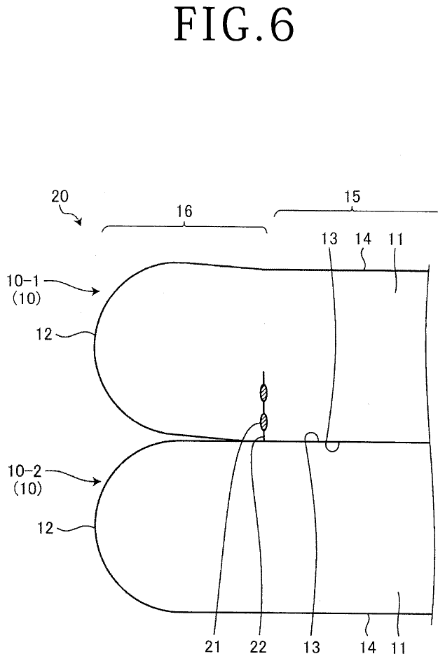

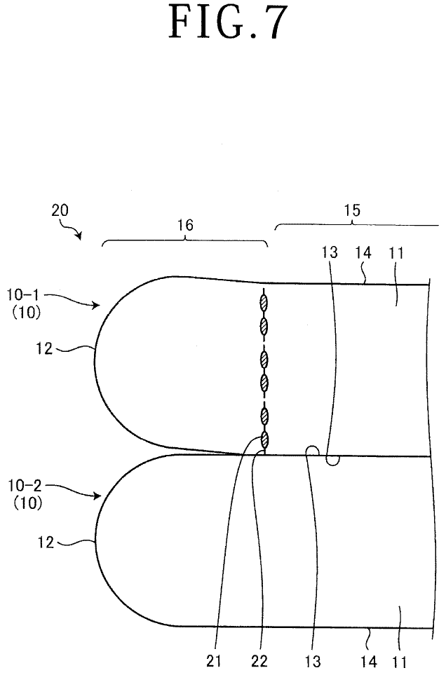

FIG. 5 is a partially sectional side view illustrating one state of the modified layer forming step 102 illustrated in FIG. 3. FIGS. 6 and 7 are sectional views illustrating part of the bonded wafer 20 after the modified layer forming step 102 illustrated in FIG. 3 in an enlarged manner. The modified layer forming step 102 is a step of forming an annular modified layer 21 and cracks 22 that extend from the modified layer 21 along a position separate inward from the outer circumferential edge 12 of the first wafer 10-1 by a predetermined distance.

In the modified layer forming step 102, the modified layer 21 and the cracks 22 are formed inside the first wafer 10-1 by stealth dicing by a laser processing apparatus 40. The laser processing apparatus 40 includes a holding table 41 and a laser beam irradiation unit 42. The holding table 41 holds the wafer 10 on a holding surface and can turn around the perpendicular axial center. The laser beam irradiation unit 42 irradiates the wafer 10 (first wafer 10-1) held by the holding table 41 with a laser beam 43. The laser processing apparatus 40 further includes a movement unit that is not illustrated and relatively moves the holding table 41 and the laser beam irradiation unit 42, an imaging unit that is not illustrated and images the wafer 10 held by the holding table 41, and so forth.

In the modified layer forming step 102, the annular modified layer 21 is formed inside the first wafer 10-1 by executing irradiation with the laser beam 43 along the position separate inward from the outer circumferential edge 12 of the first wafer 10-1 by the predetermined distance from the side of the back surface 14 of the first wafer 10-1. Specifically, the position separate inward from the outer circumferential edge 12 by the predetermined distance is the boundary between the central region 15 and the outer circumferential region 16. The laser beam 43 is a laser beam with such a wavelength as to be transmitted through the first wafer 10-1 and is, for example, infrared rays (IR).

The modified layer 21 means a region in which the density, the refractive index, the mechanical strength, or another physical characteristic has become a different state from that of the surroundings due to the irradiation with the laser beam 43. For example, the modified layer 21 is a melting treatment region, a crack region, a breakdown region, a refractive index change region, a region in which these regions exist in a mixed manner, and the like. In the modified layer 21, the mechanical strength and the like are lower than in the other part of the first wafer 10-1.

In the modified layer forming step 102, first, the side of the back surface 14 of the second wafer 10-2 is sucked and held on the holding surface (upper surface) of the holding table 41. Next, position adjustment between the first wafer 10-1 and a light collector of the laser beam irradiation unit 42 is executed. Specifically, the holding table 41 is moved to an irradiation region below the laser beam irradiation unit 42 by the movement unit that is not illustrated. Next, by shooting the first wafer 10-1 by the imaging unit that is not illustrated and executing alignment, an irradiation part of the laser beam irradiation unit 42 is made opposed, in the vertical direction, to the position separate inward from the outer circumferential edge 12 of the first wafer 10-1 by the predetermined distance. Thereafter, a focal point 44 of the laser beam 43 is set inside the first wafer 10-1.

In the modified layer forming step 102, subsequently, irradiation with the pulsed laser beam 43 from the laser beam irradiation unit 42 is executed from the side of the back surface 14 of the first wafer 10-1 while the holding table 41 is rotated around the perpendicular axial center. That is, the irradiation with the laser beam 43 is executed along the position separate inward from the outer circumferential edge 12 of the first wafer 10-1 by the predetermined distance in an annular manner.

Thereby, in the first wafer 10-1, the annular modified layer 21 along the position separate inward from the outer circumferential edge 12 by the predetermined distance is formed and the cracks 22 extend from the modified layer 21. As illustrated in FIG. 6, in the modified layer forming step 102, it is preferable to form the modified layer 21 by the irradiation with the laser beam 43 in such a manner that the cracks 22 that extend from the modified layer 21 appear on the side of the front surface 13 of the first wafer 10-1. Note that the cracks 22 may appear not only on the side of the front surface 13 of the first wafer 10-1 but also on the side of the back surface 14 as illustrated in FIG. 7.

Moreover, in the modified layer forming step 102, a plurality of modified layers 21 along the direction perpendicular to the front surface 13 of the first wafer 10-1 may be formed by executing irradiation with the laser beam 43 a plurality of times with change in the height of the focal point 44 of the laser beam 43 or executing irradiation with the laser beam 43 having a plurality of focal points 44 separate in the thickness direction of the first wafer 10-1. Furthermore, the laser beam 43 made to branch in the traveling direction of the laser beam 43 may be used or the laser beam 43 made to branch in the direction orthogonal to the traveling direction may be used. Alternatively, the laser beam 43 with an elliptical shape having a major axis along the traveling direction and a minor axis along the direction orthogonal to the traveling direction may be used.

Note that the modified layers 21 are sequentially formed from the side of the front surface 13 toward the side of the back surface 14 in the case of executing irradiation with the laser beam 43 from the side of the back surface 14 of the first wafer 10-1 a plurality of times. Furthermore, the state in which the cracks 22 are perpendicular to the front surface 13 of the first wafer 10-1 refers to the state in which the inclination of an approximate plane obtained by approximating the whole of the extending cracks 22 to a plane with respect to the perpendicular plane is within +5 degrees, preferably +2 degrees.

As illustrated in FIGS. 6 and 7, in the first wafer 10-1, warpage that causes the side of the front surface 13 to become a convex shape is caused in the outer circumferential region 16 on the side of the outer circumferential edge 12 relative to the modified layer 21 and the cracks 22 due to the formation of the modified layer 21 and the cracks 22. When the modified layer 21 and the cracks 22 have been annularly formed in the first wafer 10-1 along the whole circumference of the first wafer 10-1, the modified layer forming step 102 is ended.

In the present invention, in the modified layer forming step 102, an auxiliary modified layer and auxiliary cracks that extend from this auxiliary modified layer may be formed in the outer circumferential region 16 in addition to the modified layer 21 and the cracks 22 in order to promote the warpage of the outer circumferential region 16. For example, the auxiliary modified layer may be formed into one or multiple annular shapes concentric with the modified layer 21.

Alternatively, the auxiliary modified layer may be formed into a plurality of straight line shapes along one direction parallel to the front surface 13 (stripe shape) or a plurality of straight line shapes along two directions parallel to the front surface 13 (lattice shape).

### (Detection Step 103)

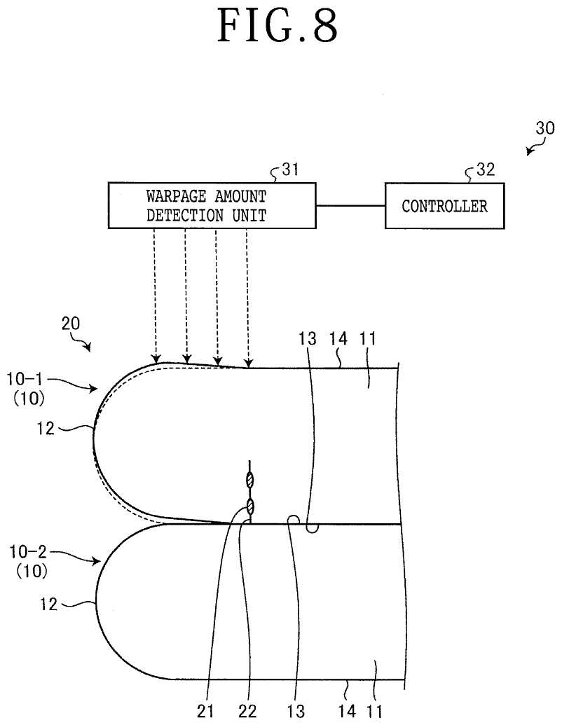

FIG. 8 is a schematic diagram illustrating one example of the detection step 103 illustrated in FIG. 3. The detection step 103 is executed after the modified layer forming step 102 is executed. The detection step 103 is a step of detecting the amount of warpage of the outer circumferential region 16 of the first wafer 10-1.

In the detection step 103 of the embodiment, the amount of warpage of the outer circumferential region 16 of the first wafer 10-1 is detected by a warpage amount detection unit 31 of the processing apparatus 30 illustrated in FIG. 8. The processing apparatus 30 includes the warpage amount detection unit 31 and a controller 32. The warpage amount detection unit 31 detects the amount of warpage of the outer circumferential region 16 and outputs the detection result to the controller 32. The controller 32 includes a calculation processing apparatus, a storage apparatus, and an input-output interface and executes various kinds of calculation processing on the basis of a program stored in the storage apparatus.

The warpage amount detection unit 31 of the embodiment includes a height measuring instrument that detects the amount of warpage of the outer circumferential region 16 by measuring the height of the outer circumferential region 16. The height measuring instrument may be either a contact type or a contactless type and includes a laser length measuring instrument, a line scanner, a three-dimensional scanner, and the like. The height measuring instrument measures the height of a predetermined measurement point in the back surface 14 in the outer circumferential region 16 of the first wafer 10-1 in the bonded wafer 20 held at a horizontal posture.

By the height measuring instrument, measurement values of a plurality of measurement points are acquired along the radial direction of the first wafer 10-1. Specifically, for example, measurement values are acquired regarding the central region 15, the position at which the modified layer 21 is formed, and the outer circumferential region 16. This can detect the amount of warpage that is the relative height at each measurement point based on the height in the central region 15.

In the present invention, the height of the outer circumferential region 16 may be measured by using an IR camera instead of the height measuring instrument. With the IR camera, the outer circumferential region 16 is irradiated with light and the bonded wafer 20 is imaged in a planar field of view. Interference fringes are formed by interference between reflected light from the side of the front surface 13 of the first wafer 10-1 and reflected light from the side of the front surface 13 of the second wafer 10-2. The IR camera identifies the height of each region on the basis of the brightness and darkness of the interference fringes on the acquired taken image and position information thereof. This can detect the amount of warpage that is the relative height in each region based on the height in the central region 15.

In the present invention, the amount of warpage of the outer circumferential region 16 may be detected by an interferometer instead of the height measuring instrument. The interferometer includes a white light interferometer and the like. With the interferometer, the gap in the outer circumferential region 16 between the first wafer 10-1 and the second wafer 10-2, formed due to the warpage of the first wafer 10-1, is irradiated with light such as IR illumination light or laser light from the outside of the bonded wafer 20 in the radial direction and reflected light is received. By the interferometer, interference fringes formed by causing convergence (recombination) of reflected light of the measurement surface (outer circumferential region 16) and reflected light of a reference surface (mirror of the interferometer) are acquired and the amount of warpage, which is the size of the gap, can be detected on the basis of the number of interference fringes.

The processing apparatus 30 may be part of the laser processing apparatus 40 that executes the modified layer forming step 102 and is illustrated in FIG. 5. In this case, the warpage amount detection unit 31 is installed movably relative to the holding table 41. Moreover, the controller 32 may be included in a control apparatus of the laser processing apparatus 40.

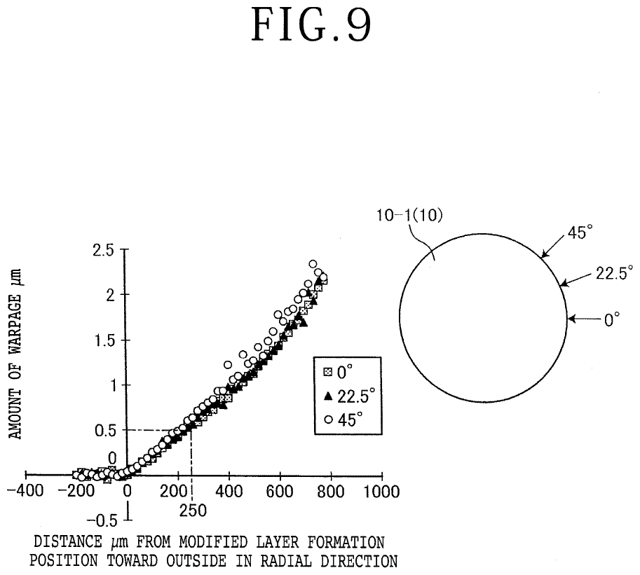

FIG. 9 is a diagram illustrating one example of a measurement result of the amount of warpage in the detection step 103 illustrated in FIG. 3. FIG. 9 is a graph indicating a relation between a distance [μm] from the position at which the modified layer 21 is formed toward the outside in the radial direction and the amount of warpage [μm] at positions at 0 degrees, 22.5 degrees, and 45 degrees from a predetermined position in the first wafer 10-1 in the circumferential direction.

It turns out that, in the example illustrated in FIG. 9, the amount of warpage reaches 0.5 μm at a position at approximately 200 μm from the position at which the modified layer 21 is formed at all measurement positions. Note that, although the amount of warpage at positions at at most 800 μm from the position at which the modified layer 21 is formed is detected in the example illustrated in FIG. 9, detection may be executed only regarding a small region such as a region of +100 μm in the radial direction from the position at which the modified layer 21 is formed in the detection step 103 of the present invention.

### (Determination Step 104)

The determination step 104 is a step of determining whether or not the bonding between the first wafer 10-1 and the second wafer 10-2 in the outer circumferential region 16 has been released on the basis of the amount of warpage of the outer circumferential region 16 of the first wafer 10-1 detected in the detection step 103 and deciding whether or not to execute the grinding step 105.

The determination step 104 of the embodiment is executed by the controller 32 of the processing apparatus 30 illustrated in FIG. 8. In the determination step 104, for example, when the amount of warpage is smaller than a predetermined value at a position separate outward in the radial direction by a predetermined distance from the position at which the modified layer 21 is formed, the controller 32 determines that the bonding between the first wafer 10-1 and the second wafer 10-2 has not been released, and decides not to execute the grinding step 105.

For example, in the embodiment, when the amount of warpage at a position separate outward in the radial direction by 250 μm from the position at which the modified layer 21 is formed is smaller than 0.5 μm, it is determined that the bonding between the first wafer 10-1 and the second wafer 10-2 has not been released. In the case in which the amount of warpage of the outer circumferential region 16 has been detected at a plurality of places in the circumferential direction of the first wafer 10-1 in the detection step 103, for example, an average, a median, a lower-limit value, or the like may be employed as the measurement value of the amount of warpage. For example, in the example illustrated in FIG. 9, the amount of warpage at the position separate outward in the radial direction by 250 μm from the position at which the modified layer 21 is formed is equal to or larger than 0.5 μm, it is determined that the bonding between the first wafer 10-1 and the second wafer 10-2 has been released.

In the processing method of the wafer 10 in the embodiment, the grinding step 105 is executed when it is determined that the amount of warpage of the outer circumferential region 16 is equal to or larger than the predetermined value in the determination step 104 (determination step 104; Yes). Furthermore, in the processing method of the wafer 10 in the embodiment, the modified layer forming step 102 is executed when it is determined that the amount of warpage of the outer circumferential region 16 is smaller than the predetermined value in the determination step 104 (determination step 104; No).

In the processing method of the wafer 10 in the embodiment, the modified layer forming step 102, the detection step 103, and the determination step 104 are repeatedly executed until it is determined that the amount of warpage of the outer circumferential region 16 is equal to or larger than the predetermined value in the determination step 104 (determination step 104; Yes). In the present invention, for example, after the modified layer forming step 102 is executed again, it may be deemed that the bonding between the first wafer 10-1 and the second wafer 10-2 in the outer circumferential region 16 has been released, and the grinding step 105 may be executed.

For example, in the first modified layer forming step 102, the modified layer 21 may be formed in such a manner that the cracks 22 appear on the side of the front surface 13 of the first wafer 10-1 as illustrated in FIG. 6. Then, in the modified layer forming step 102 executed as the second round thereof, the modified layer 21 may be formed in such a manner that the cracks 22 appear on the side of the back surface 14 of the first wafer 10-1 as illustrated in FIG. 7. Moreover, in the modified layer forming step 102 executed as the third round thereof, the above-described auxiliary modified layer and auxiliary cracks may be formed in the outer circumferential region 16.

### (Grinding Step 105)

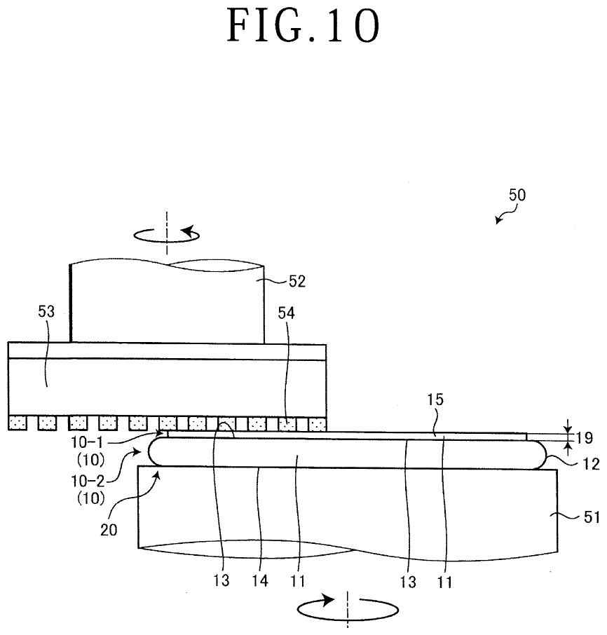

FIG. 10 is a partially sectional side view illustrating one state of the grinding step 105 illustrated in FIG. 3. The grinding step 105 is executed on the basis of the determination result of the determination step 104. The grinding step 105 of the embodiment is executed when it is determined that the amount of warpage of the outer circumferential region 16 of the first wafer 10-1 is equal to or larger than the predetermined value in the determination step 104. The grinding step 105 is a step of grinding the first wafer 10-1 of the bonded wafer 20 from the side of the back surface 14 to thin the first wafer 10-1 to the finished thickness 19.

In the grinding step 105 of the embodiment, by a grinding apparatus 50, the side of the back surface 14 of the first wafer 10-1 is ground to thin the first wafer 10-1 to the predetermined finished thickness 19. The grinding apparatus 50 includes a holding table 51, a spindle 52 that is a rotating shaft component, a grinding wheel 53 attached to the lower end of the spindle 52, grinding abrasive stones 54 mounted on the lower surface of the grinding wheel 53, and a grinding liquid supply unit that is not illustrated. The grinding wheel 53 rotates around a rotation axis parallel to the axial center of the holding table 51.

In the grinding step 105, first, the side of the back surface 14 of the second wafer 10-2 is sucked and held on a holding surface of the holding table 51. Next, the grinding wheel 53 is rotated around the axial center in the state in which the holding table 51 is rotated around the axial center. A grinding liquid is supplied to a processing point by the grinding liquid supply unit that is not illustrated. In addition, the grinding abrasive stones 54 of the grinding wheel 53 are brought closer to the holding table 51 at a predetermined feed rate. Thereby, the back surface 14 of the first wafer 10-1 is ground by the grinding abrasive stones 54 to thin the first wafer 10-1 to the predetermined finished thickness 19.

At this time, by an external force of pressing of the ground surface of the first wafer 10-1 by the grinding abrasive stones 54, an end material of the outer circumferential region 16 of the first wafer 10-1 is removed in such a manner that the modified layer 21 serves as the point of origin and the modified layer 21 and the cracks 22 are the boundary surface.

### Modification Example

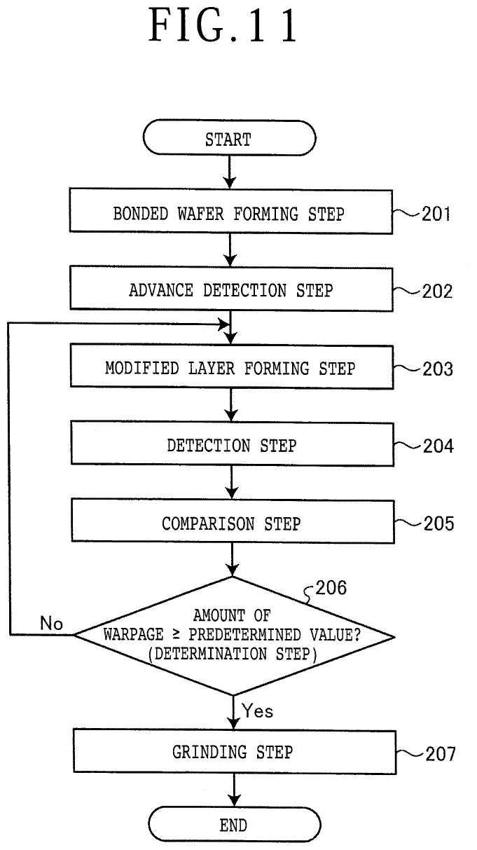

A processing method of the wafer 10 according to a modification example of the present invention will be described on the basis of a drawing. FIG. 11 is a flowchart illustrating the flow of the processing method of the wafer 10 according to the modification example. As illustrated in FIG. 11, the processing method of the wafer 10 in the modification example includes a bonded wafer forming step 201, an advance detection step 202, a modified layer forming step 203, a detection step 204, a comparison step 205, a determination step 206, and a grinding step 207.

Note that the bonded wafer forming step 201, the modified layer forming step 203, and the grinding step 207 of the modification example are procedures similar to the bonded wafer forming step 101, the modified layer forming step 102, and the grinding step 105 of the embodiment and therefore description thereof is omitted.

### (Advance Detection Step 202)

The advance detection step 202 is executed before the modified layer forming step 203 is executed. The advance detection step 202 is a step of detecting the amount of warpage of the outer circumferential region 16 of the first wafer 10-1 in advance. The advance detection step 202 is executed in a procedure similar to that of the detection steps 103 and 204 with similar equipment and condition. The measurement value of the amount of warpage of the outer circumferential region 16 detected in the advance detection step 202 is output to the controller 32 and is stored in the storage apparatus of the controller 32.

### (Comparison Step 205 and Determination Step 206)

The comparison step 205 is a step of comparing the amount of warpage of the outer circumferential region 16 of the first wafer 10-1 detected in the advance detection step 202 with the amount of warpage of the outer circumferential region 16 of the first wafer 10-1 detected in the detection step 204. Furthermore, in the determination step 206 of the modification example, whether or not the bonding between the first wafer 10-1 and the second wafer 10-2 in the outer circumferential region 16 has been released is determined on the basis of the comparison result in the comparison step 205 and whether or not to execute the grinding step 207 is decided.

In the embodiment, it is deemed that the outer circumferential region 16 of the first wafer 10-1 does not warp before execution of the modified layer forming step 102 and the height of the outer circumferential region 16 before execution of the modified layer forming step 102 is the same as that of the central region 15 detected in the detection step 103. In contrast, in the modification example, the actual measurement value detected in the advance detection step 202 is used as a reference value.

As described above, in the processing methods of the wafer 10 and the processing apparatus 30 according to the embodiment and the modification example, after the annular modified layer 21 is formed along the outer circumferential edge 12 of the first wafer 10-1, it is checked whether or not the bonding between the first wafer 10-1 and the second wafer 10-2 has been released in the outer circumferential region 16 on the side of the outer circumferential edge 12 relative to the modified layer 21. This allows detection of processing failure and additional processing before execution of the subsequent grinding step 105 or 207. Therefore, it is possible to suppress the occurrence of the situation in which an end material remains without being separated in the grinding processing or processing failure such as the breakage of the wafer 10 or damage to the device 18 occurs. Thus, an effect of improvement in the yield is provided.

Note that the present invention is not limited to the above-described embodiment and modification example. That is, the present invention can be carried out with various modifications without departing from the gist of the present invention.

For example, height measurement may be executed regarding not only the outer circumferential region 16 of the first wafer 10-1 but the whole surface in the advance detection step 202 and the detection steps 103 and 204. This can reduce debris that adheres to the back surface 14 of the first wafer 10-1 and noise such as concavities and convexities in the holding table 41 (see FIG. 5) from the difference in the height between before and after the modified layer forming step 203.

Moreover, the outer circumferential region 16 may be removed in advance by giving an external force before execution of the grinding step 105. Specifically, for example, it is possible to employ a method in which the outer circumferential region 16 is pressed from the upper side to give an external force in a shear direction or a method in which the outer circumferential region 16 is lifted up to give an external force in a shear direction. Alternatively, the outer circumferential region 16 may be crushed by a roller. Furthermore, the measure for the removal of the outer circumferential region 16 is not limited to the mechanical external force and may be vibrations based on ultrasonic waves or an external force in the radial direction given by sticking an expanding tape to the back surface 14 of the first wafer 10-1 and expanding the expanding tape.

Furthermore, it is possible that the first wafer 10-1 does not have the devices 18 on the front surface 13 and the second wafer 10-2 has the devices 18 on the front surface 13. In this case, irradiation with the laser beam 43 may also be executed from the side of the back surface 14 of the first wafer 10-1 to the bonded wafer 20 in which the front surface 13 of the first wafer 10-1 and the front surface 13 of the second wafer 10-2 are bonded to each other.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing method of a wafer, comprising:
a bonded wafer forming step of forming a bonded wafer by bonding a front surface side of a first wafer to a second wafer, the first wafer having an outer circumferential chamfered edge;
a modified layer forming step of, after execution of the bonded wafer forming step, executing irradiation with a laser beam with such a wavelength as to be transmitted through the first wafer from a back surface side of the first wafer along a position separate inward from the outer circumferential edge by a predetermined distance in an annular manner and forming, inside the first wafer, an annular modified layer and cracks that extend from the modified layer and extend toward the front surface side of the first wafer to cause warpage in an outer circumferential region on a side of the outer circumferential edge relative to the modified layer and the cracks;
a detection step of detecting an amount of warpage of the outer circumferential region of the first wafer after execution of the modified layer forming step;
a determination step of determining whether or not bonding between the first wafer and the second wafer in the outer circumferential region has been released on a basis of the amount of warpage of the outer circumferential region detected in the detection step; and
a grinding step of grinding the first wafer of the bonded wafer from the back surface side to thin the first wafer to a finished thickness when it is determined that the amount of warpage of the outer circumferential region is equal to or larger than a predetermined value in the determination step.

2. The processing method of a wafer according to claim 1, wherein
the modified layer forming step is executed again when it is determined that the amount of warpage of the outer circumferential region is smaller than the predetermined value in the determination step.

3. The processing method of a wafer according to claim 1, further comprising:
an advance detection step of detecting the amount of warpage of the outer circumferential region in advance before the execution of the modified layer forming step; and
a comparison step of comparing the amount of warpage detected in the advance detection step with the amount of warpage detected in the detection step, wherein,
in the determination step, whether or not the bonding between the first wafer and the second wafer in the outer circumferential region has been released is determined on a basis of a comparison result in the comparison step and whether or not to execute the grinding step is decided.

4. The processing method of a wafer according to claim 1, wherein,
in the detection step, a height of the outer circumferential region is measured and the amount of warpage of the outer circumferential region is detected on a basis of a measurement value of the height of the outer circumferential region.

5. The processing method of a wafer according to claim 1, wherein,
in the detection step, the outer circumferential region is irradiated with light, an interference fringe is acquired, and the amount of warpage of the outer circumferential region is detected on a basis of the interference fringe generated in the outer circumferential region.
